(19) United States
(12) Patent Application Publication
(10) Pub. No.: US 2016/0348865 A1
(43) Pub. Date: Dec. 1, 2016

(54) VEHICLE HEADLIGHT SYSTEM

(71) Applicant: Stanley Electric Co., Ltd., Tokyo (JP)

(72) Inventor: Katsunori Nakazawa, Tokyo (JP)

(21) Appl. No.: 15/160,770

(22) Filed: May 20, 2016

(30) Foreign Application Priority Data
May 25, 2015 (JP) 2015-107267

(51) Int. Cl. F21S 8/10; F21V 9/16; H01S 5/00; B60Q 1/14; H01S 5/042; H01S 5/0683; H05B 37/02; H05B 37/03

(52) U.S. Cl. CPC F21S 48/1145; H05B 37/0227; F21S 48/1225; F21V 9/16; H05B 37/03; B60Q 1/1423; F21S 48/125; F21S 48/13; H01S 5/042; H01S 5/0683; H01S 5/005; F21Y 2101/025

(57) ABSTRACT

A headlight system can include a laser driving circuit to drive a laser device, a detecting circuit to detect a current of the laser device, a wavelength converting material to emit light having a white color tone associated with the laser device, a receiver circuit to detect a light-intensity of the light via a photo detector and a controller. The controller can control the laser driving circuit while watching normal/abnormal states of an optical structure of the system. Thus, the disclosed subject matter can provide the headlight system, which can provide favorable light distribution patterns by using the light, even when a battery voltage returns the laser device to the normal state after the controller outputs a turn-off signal to the laser driving circuit not to emit the laser device by detecting the abnormal state in the optical structure such as the laser device because the battery voltage largely decreases.

This application claims the priority benefit under 35 U.S.C. §119 of Japanese Patent Application No. 2015-107267 filed on May 25, 2015, which is hereby incorporated in its entirety by reference.

### BACKGROUND

1. Field

The presently disclosed subject matter relates to vehicle headlight systems, and more particularly to vehicle headlight systems including a semiconductor laser device and a fail-safe circuit, which can provide favorable light distribution patterns having a high light-intensity to safely drive at night, by immediately returning the semiconductor laser device to a turn-on state even when the fail-safe circuit turns off the semiconductor laser device once because a battery voltage largely decreases due to a large load such as a starter, etc.

2. Description of the Related Art

Recently, vehicle headlight systems using a semiconductor laser device as a light source have been developed. The vehicle headlight systems may provide favorable light distribution patterns having a high light-intensity by using the semiconductor laser device as the light source, as compared with conventional vehicle headlights using a halogen bulb, a high-intensity discharge lamp and the like as the light source. As such the vehicle headlight systems using the semiconductor laser device, for example, Patent document No. 1 (Japanese Patent Application Laid Open JP 2014-180886), Patent document No. 2 (Japanese Patent Application Laid Open JP 2013-191479) and the like are disclosed by Applicant of this disclosed subject matter.

The vehicle headlight systems using the semiconductor laser device may emit light having a high energy density, and therefore may frequently include means to automatically stop emitting the light having a high energy density in view of eye-safe systems, when a breakdown of the headlight systems occurs. Each of the vehicle headlight systems of the above-described Patent documents No. 1 and No. 2 also includes a fail-safe circuit. FIG. 4 is a schematic cross-sectional side view depicting a conventional vehicle headlight having the fail-safe circuit using a laser chip, which is disclosed in Patent document No. 1.

The conventional vehicle headlight system 50 includes: a lens holder 52; a projector lens 56 having an optical axis AX attached to lens holder 52; a photo detecting holder 53A; a reflector holder 53B located adjacent the photo detecting holder 53A; a photo detector 59 attached between the photo detecting holder 53A and the reflector holder 53; a wavelength converting plate 55 attached to an opening of the reflector 53B; a laser device 54 having a laser chip 51C attached between the reflector holder 53B and a laser device holder 54, and the laser chip 51C configured to emit a laser beam toward the wavelength converting plate 55; a radiator 58 connected to the laser device holder 54 to efficiently radiate heat generated from the laser device 54; a first reflector 57A configured to reflect white light emitted from the laser device 54 via the wavelength converting plate 55 toward the projector lens 56; a second reflector 57B configured to direct a slightly part of the white light reflected by the first reflector 57A toward the photo detector 59; and a controller 60 configured to project the white light from the projector lens 56 in a forward direction of the vehicle headlight system 50 in accordance with a lighting signal output from a subject vehicle incorporating the headlight system 50.

According to the conventional vehicle headlight system 50, the white light emitted from the laser device 54 via the wavelength converting plate 55 can be projected from the projector lens 56 via the first reflector 57A by the controller 60 in the forward direction of the vehicle headlight system 50, which is incorporated into the subject vehicle. If the breakdown of the headlight systems 50 occurs, the photo detector 59 may detect the breakdown by detecting, for example, an abnormal light, which differs from the normal white light, and also may output an abnormal signal to the controller 60 to stop emitting the laser beam.

Structures disclosed in Patent document No. 2 may be similar in attitude of the structure of the vehicle headlight system 50, and therefore descriptions thereof will be abbreviated here. These structures may include controllers to drive each of semiconductor laser devices so that each of amounts of lights emitted from the laser devices can be maintained at a constant amount even when a supply voltage varies in some degree of rated voltage.

A voltage supplied from a vehicular battery may vary with increasing degree of a load, which is supplied from the vehicular battery. The battery voltage may largely degrease due to a large load of starter when drivers start up an engine. When the battery voltage largely degreases, a driving circuit to drive a semiconductor laser device may frequently stop a voltage supplied from the battery to the laser device or may degrease the voltage supplying to the laser device because of increasing a load to the battery. In these cases, the semiconductor laser device may turn off or may emit light having a low light-intensity in a forward direction of a subject vehicle.

By contrast, the above-described photo detector 59, which may detect an abnormal state in an optical structure such as the laser device 54, the wavelength converting plate 55, etc., may operate at a relatively low voltage (e.g., 3 to 5 volts). Accordingly, the photo detector 59 may output a turn-off signal to the controller 60 to turn off the laser device 54 by detecting the abnormal state in the optical structure when the battery voltage largely decreases.

However, even when the battery voltage returns a normal state after that, because the photo detector 59 must keep an output state of the turn-off signal to the controller 60 to turn off the laser device 54, the controller 60 may not turn on the laser device 54. Therefore, once the photo detector 59 outputs a turn-off signal to the controller 60 to turn off the laser device 54 in such a case, the conventional headlight systems may include a problem such that the controller 60 must turn on the semiconductor laser device 54 after turning off the battery voltage connecting the controller 60 to operate the laser device 54 once.

The above-referenced Patent Documents and additional Patent Documents are listed below and are hereby incorporated with their English abstracts and specification in their entireties.

### 1. Patent Document No. 1: Japanese Patent Application Laid Open JP 2014-180886

### 2. Patent Document No. 2: Japanese Patent Application Laid Open JP 2013-191479

### 3. Patent Document No. 3: Japanese Patent Application Laid Open JP 2015-064278

4. Patent Document No. 4: U.S. Pat. No. 9,147,814 (Attorney docket No. ST3001-0398)

The disclosed subject matter has been devised to consider the above and other problems, characteristics and features. Thus, exemplary embodiments of the disclosed subject matter can include vehicle headlight systems, which can provide a favorable light distribution pattern to safely drive at night, while watching an abnormal state in an optical structure such as a semiconductor laser device, a wavelength converting material, etc. A controller of the vehicle headlight systems can detect the abnormal state in the optical structure by determining whether a light-intensity received from a receiver circuit is lower than a threshold stored at a threshold memory or not. Accordingly, the controller can enable a laser driving circuit not to emit a laser beam from the semiconductor laser device by outputting a turn-off signal to the laser driving circuit, and the laser driving circuit can also detect that the power supply voltage becomes higher than a predetermined value.

Therefore, when the power supply voltage becomes higher than the predetermined value, the laser driving circuit can apply the power supply voltage to the semiconductor laser device so as to be able to emit the laser beam from the semiconductor laser device, even when the battery voltage returns a normal state after the controller outputs the turn-off signal to the semiconductor laser device by detecting the abnormal state in the optical structure because the battery voltage largely decreases due to a large load of starter, etc.

### SUMMARY

The presently disclosed subject matter has been devised in view of the above and other characteristics, desires, and problems in the conventional art. An aspect of the disclosed subject matter can provide vehicle headlight systems, which can provide a favorable light distribution pattern by using light having the substantially white color tone wavelength-converted by a wavelength converting material and a laser beam having a high light-intensity emitted from a semiconductor laser device via a light distribution adjustment to safely drive at night, even when a battery voltage immediately returns the semiconductor laser device to a normal state after a controller outputs a turn-off signal to a laser driving circuit so as not to emit the laser beam from the semiconductor laser device by detecting an abnormal state in an optical structure such as the semiconductor laser device, the wavelength converting material and the like, because the battery voltage largely decreases due to a large load such as a starter, etc.

According to an aspect of the disclosed subject matter, a vehicle headlight system can include: a laser driving circuit configured to receive a power supply from a battery incorporated into a subject vehicle, which incorporates the vehicle headlight system, via a headlight switch; a semiconductor laser device configured to emit a laser beam by the laser driving circuit; a current detector configured to detect a current flowing from the laser driving circuit into the laser device; a wavelength converting material configured to emit light having a substantially white color tone using the laser beam emitted from the laser device; a light distribution adjustment configured to receive the light having the substantially white color tone from the wavelength converting material, and configured to provide light distribution patterns in a forward direction of the subject vehicle by using the light emitted from the wavelength converting material; a photo detector configured to receive a part of the light emitted from the wavelength converting material; and a receiver circuit configured to detect a light-intensity of the part of the light received by the photo detector.

In addition, the vehicle headlight system can also include: a controller including a threshold memory, configured to output a turn-on signal to the laser driving circuit after the controller is initialized when the headlight switch turns on, and configured to output a turn-off signal to the laser driving circuit when the light-intensity received from the receiver circuit is lower than a threshold stored at the threshold memory; a constant voltage circuit configured to apply a substantially constant voltage to the controller; and wherein the laser driving circuit is configured to emit the laser beam from the laser device when a power supply voltage received from the battery is higher than a predetermined voltage after the laser driving circuit inputs the turn-on signal output from the controller.

In the above-described exemplary vehicle headlight system, a resistance can connect between the laser driving circuit and the laser device as the current detector, and a blue laser chip can be employed as a laser chip for the laser device. The wavelength converting material can include at least one of a red phosphor, a green phosphor, a blue phosphor and an yellow phosphor, and also the light distribution adjustment can include at least one of at least one reflector and a projector lens. In this case, a blue laser chip emitting a blue laser beam can be employed as the laser chip for the laser device, and an yttrium aluminum garnet (YAG) phosphor ceramic can be employed as the wavelength converting material so as to be able to emit light having a substantially white color tone from the light distribution adjustment. Additionally, the controller can include a computer system including a central processing unit (CPU), a read-only memory (ROM), a random access memory (RAM), and also at least one of the receiver circuit and the detecting circuit can be integrated into the controller. Moreover, the controller can store a plurality of thresholds at the threshold memory, and the controller can also store a lower threshold with a decrease in the current value, which flows from the laser driving circuit to the laser device, at the threshold memory.

Furthermore, in the above-described exemplary vehicle headlight systems, the constant voltage circuit can apply either substantially 3.3 volts or 5 volts to the controller, which may operate in a stable state. The predetermined voltage in order for the laser driving circuit to emit the laser beam from the semiconductor laser device can be setup between 9 volts and 18 volts so that the vehicle headlight system can a favorable light distribution pattern by using the light having the substantially white color tone wavelength-converted by the wavelength converting material and the laser beam having a high light-intensity emitted from the semiconductor laser device via the light distribution adjustment to safely drive at night.

According to the aspect of the disclosed subject matter, the controller can detect an abnormal state in an optical structure such as the laser device, the wavelength converting material and the like by detecting whether the light-intensity received from the receiver circuit is lower than the threshold stored at the threshold memory or not. Accordingly, the controller can enable the laser driving circuit not to emit the laser beam from the semiconductor laser device by outputting the turn-off signal to the laser driving circuit, and the laser driving circuit can also detect that the power supply voltage becomes higher than the predetermined value. When the power supply voltage becomes higher than the predetermined value, the laser driving circuit can apply the power supply voltage to the semiconductor laser device so as to be able to emit the laser beam form the semiconductor laser device.

Thus, the disclosed subject matter can provide vehicle headlight systems, which can provide a favorable light distribution pattern by using the light having the substantially white color tone wavelength-converted by the wavelength converting material and the laser beam having the high light-intensity, even when a battery voltage immediately returns the semiconductor laser device to a normal state after a controller outputs a turn-off signal to a laser driving circuit so as not to emit the laser beam from the semiconductor laser device by detecting an abnormal state in an optical structure such as the semiconductor laser device, the wavelength converting material and the like, because the battery voltage largely decreases due to a large load such as a starter, etc.

### BRIEF DESCRIPTION OF THE DRAWINGS

These and other characteristics and features of the disclosed subject matter will become clear from the following description with reference to the accompanying drawings, wherein:

FIG. 1 is a block diagram showing an exemplary embodiment of a vehicle headlight system including a semiconductor laser device and a favorable fail-safe circuit made in accordance with principles of the disclosed subject matter;

FIGS. 2a and 2b are tables to explain exemplary methods for set-upping one threshold and for set-upping a plurality of thresholds in the vehicle headlight system shown in FIG. 1, respectively;

FIGS. 3a and 3b are flow charts showing exemplary operations of a laser driving circuit and a controller in the vehicle headlight system shown in FIG. 1, respectively; and

FIG. 4 is a schematic cross-sectional side view depicting a conventional vehicle headlight having a fail-safe circuit using a laser device.

### DETAILED DESCRIPTION OF EXEMPLARY EMBODIMENTS

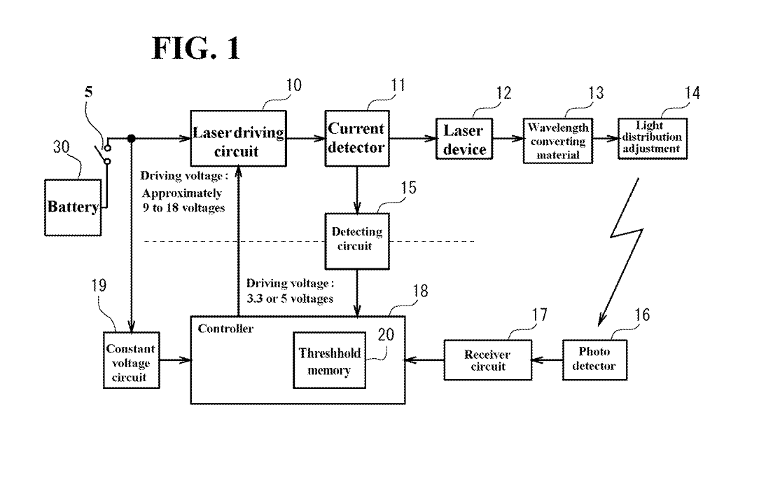

The disclosed subject matter will now be described in detail with reference to FIG. 1 to FIG. 3. FIG. 1 is a block diagram showing an exemplary embodiment of a vehicle headlight system including a semiconductor laser device and a favorable fail-safe circuit made in accordance with principles of the disclosed subject matter. The vehicle headlight system can provide favorable light distribution pattern having a high light-intensity in a forward direction of a subject vehicle incorporating the vehicle headlight system, which is operated by using a vehicle battery 30 incorporated into the subject vehicle.

The vehicle headlight system can include: a laser driving circuit 10 receiving a power supply from a battery 30 in corporate into the subject vehicle via a headlight switch 5; a semiconductor laser device 12 configured to emit a laser beam by the laser driving circuit 10; a current detector 11 configured to detect a current flowing from the laser driving circuit 10 into the semiconductor laser device 12; a wavelength converting material 13 configured to emit light having a substantially white color tone using the laser beam emitted from the semiconductor laser device 12; and a light distribution adjustment 14 configured to receive the light having the substantially white color tone from the wavelength converting material 13, and configured to provide favorable light distribution patterns in a forward direction of the subject vehicle by using the light emitted from the wavelength converting material 13.

In addition, the vehicle headlight system can also include: a detecting circuit 15 configured to detect current data, which flows from the laser driving circuit 10 into the semiconductor laser device 12, from the current detector 11; a photo detector 16 configured to receive a slightly part of the light, which is emitted from the wavelength converting material 13; a receiver circuit 17 configured to detect a light-intensity of the slightly part of the light, which is received by the photo detector 16; and a controller 18 including a threshold memory 20, configured to output a turn-on signal to the laser driving circuit 10 after the controller 18 is initialized when the headlight switch 5 turns on, and configured to output a turn-off signal to the laser driving circuit 10 when the light-intensity received from the receiver circuit 17 is lower than a threshold stored at the threshold memory 20.

Moreover, the vehicle headlight system can also include a constant voltage circuit 19 applying a constant voltage to the controller 18, and wherein the laser driving circuit 10 is configured to emit the laser beam from the semiconductor laser device 12 when a power supply voltage received from the battery is higher than a predetermined voltage after the laser driving circuit 11 inputs the turn-on signal output from the controller 18.

Details of the above-described elements will now be described. The laser driving circuit 10 can flow a rated constant current into the semiconductor laser device 12 so that the semiconductor laser device 12 can emit the laser beam when the laser device 12 is a laser diode. When the current flown into the semiconductor laser device 12 is detected by the current detector 11, a resistance can connect between the laser driving circuit 10 and the semiconductor laser device 12 as the current detector 11, and also a shunt resistance included in either the laser driving circuit 10 or the semiconductor laser device 12 can be used as the current detector 11. Additionally, a hole device can also be used as the current detector 11 as disclosed in Patent document No. 3, which is owned by Applicant of this disclosed subject matter.

The detecting circuit 15 can detect the current in accordance with law of Ohm by detecting a difference of voltages between both ends of the current detector 11 by using current-voltage convertor, an amplifier circuit, a comparator circuit, etc. When the hole device is used as the current detector 11, the detecting circuit 15 can detect the current by using an amplifier circuit, a comparator circuit, etc.

As a laser chip for the semiconductor laser device 11, a blue laser chip (s) having a peak wavelength of approximately 450 nanometers, for example, which is configured with InGaN series material, can be employed, and also a laser diode of InGaN series that emits an ultraviolet laser beam light having a light-emitting wavelength of approximately 380 nanometers, can be employed. In these cases, when the wavelength converting material 13 includes a red phosphor wavelength-converting the ultraviolet laser beam into red light, a green phosphor wavelength-converting the ultraviolet laser beam into green light and a blue phosphor wavelength-converting the ultraviolet laser beam into blue light, the wavelength converting material 13 can emit the light having a substantially white color tone by an additive color mixture of the above-described three color phosphors.

When the blue laser chip (S) is used as the laser chip for the semiconductor laser diode 11, the wavelength converting material 13 can be made by forming a binder including a yellow phosphor in a planar shape, and also can be made by using an yttrium aluminum garnet (YAG) phosphor ceramic, which is made by press-sintering a phosphor material dispersing the YAG phosphor into aluminum oxide. The wavelength converting material 13 can also emit the light having a substantially white color tone by an additive color mixture of a part of blue laser beam and yellow light emitted from YAG yellow phosphor excited by another part of the blue laser beam. Because detail descriptions with respect to the above-described laser chips and the wavelength converting material are disclosed in Patent document No. 4 by Applicant of this disclosed subject matter, the detail descriptions are abbreviated here.

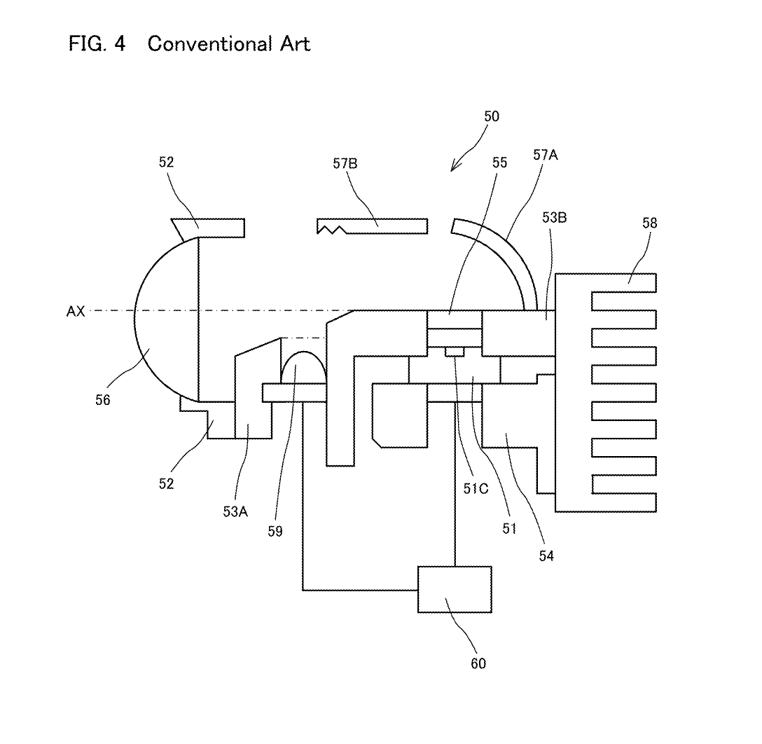

The above-described light having a substantially white color tone, which is emitted from the wavelength converting material 13, can be received by the light distribution adjustment 14, and the light distribution adjustment 14 can provide the favorable light distribution patterns in the forward direction of the subject vehicle by using the light having the substantially white color tone. As an exemplary structure of the light distribution adjustment 14 including the first reflector 57A, the second reflector 57B, the projector lens 56 as shown in FIG. 4, can be used. The exemplary structure is owned and disclosed by Applicant of this disclosed subject matter as described above, and therefore the detail descriptions will also be abbreviated here.

The photo detector 16 can also be located so as to receive the slightly part of the white light emitted from the wavelength converting material 13 as shown in FIG. 4. As the photo detector 16, a photo diode, a photo transistor and the like can be used. Although the photo detector 16 receives an indirect light via the second reflector 57B in FIG. 4, the photo detector 16 can also receive a direct light by locating the photo detector 16, for example, in a space between the first reflector 57A and the second reflector 57B, and therefore can detect the light-intensity of the light having the substantially white color tone emitted from the wavelength converting material 13, which is well correlated with a light-intensity of the laser beam emitted from the semiconductor laser device 12.

The receiver circuit 17 can detect the light-intensity of the light having the substantially white color tone, which is received by the photo detector 16, and can output light-intensity data in accordance with a value of the light-intensity to the controller 18. The controller 18 can output the turn-off signal to the laser driving circuit 10 when the controller 18 detects that the value of the light-intensity is lower than the threshold, which is stored at the threshold memory 20, which includes a hard ware architecture such as DIP switch. The above-described turn-off signal can include a signal to turn off the semiconductor laser device 11, and also can include a signal to turn on the semiconductor laser device 11 at a low eye-safe power in view of an eye safe.

The controller 18 can include a computer system including a central processing unit (CPU), a read-only memory (ROM), a random access memory (RAM) and the like, and can be operated to output the turn-off signal to the laser driving circuit 10 by running a program from the ROM while using the threshold memory 20. Thereby, the controller 18 can output the turn-off signal to the laser driving circuit 10 when the threshold memory 20 detects that the value of the light-intensity is lower than the threshold. The receiver circuit 17 and the detecting circuit 15 can also be integrated into the controller 18.

The constant voltage circuit 19 can apply a constant voltage to the controller 18 by using a battery voltage, which is supplied from the battery 30. As described in FIG. 1, an exemplary driving voltage of the laser driving circuit 10 can be approximately 9 to 18 vols, and an exemplary driving voltage of the controller 18 can be approximately 3.3 volts or 5.0 volts. The controller 18 can enable the threshold memory 20 to store variable thresholds in accordance with the current detected by the detecting circuit 15. Specifically, the controller 18 can be operated to store the variable threshold at the threshold memory 20 by running the program from the ROM while watching the current detected by the detecting circuit 15.

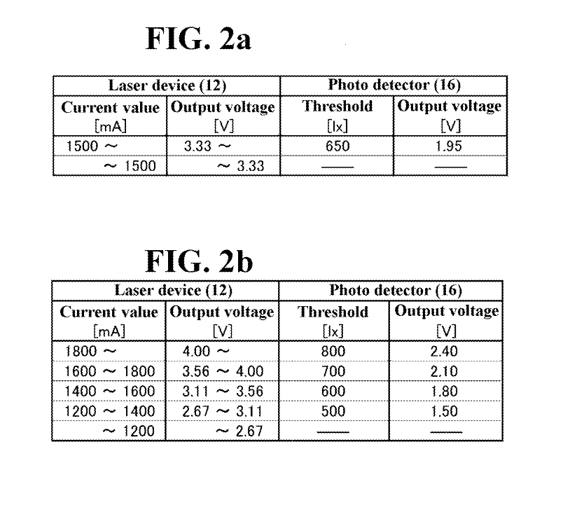

Exemplary methods for determining variable thresholds will now be described with reference to FIGS. 2a and 2b, which are tables to explain exemplary methods for set-upping one threshold and for set-upping a plurality of thresholds in the vehicle headlight system, respectively. When a current value, which flows from the laser driving circuit 10 into the semiconductor laser device 12, is 1,500 milleamperes, a voltage outputted from the detecting circuit 15 can be 3.33 volts. In this case, provided the semiconductor laser device 12 normally operates, an amount of light received by the photo detector 16 can be 650 luxes (lx) and a voltage outputted from the receiver circuit 17 corresponding to the amount of the light can be 1.95 voltages as shown in FIG. 2a.

Accordingly, the controller 18 can store 1.95 volts as the threshold at the threshold memory 20, because the controller 18 can determine that the semiconductor laser device 12 normally operates if the voltage outputted from the detecting circuit 15 is 3.33 millevoltages or more. Thereby, when the amount of the light received by the photo detector 16 is less than 650 lx, the controller 18 can output the turn-off signal to the laser driving circuit 10 so as to substantially stop applying a power supply to the semiconductor laser device 12. Exemplary methods for set-upping a plurality of thresholds will now be described with reference to FIG. 2b.

When the voltage outputted from the detecting circuit 15 is 4.00 volts or more, the controller 18 can store 2.40 volts as the threshold at the threshold memory 20, when the voltage outputted from the detecting circuit 15 is between 4.00 volts and 3.56 volts, the controller 18 can store 2.10 volts as the threshold at the threshold memory 20, when the voltage outputted from the detecting circuit 15 is between 3.56 volts and 3.11 volts, the controller 18 can store 1.80 volts as the threshold at the threshold memory 20, and When the voltage outputted from the detecting circuit 15 is between 3.11 volts and 2.67 volts, the controller 18 can store 1.50 volts as the threshold at the threshold memory 20.

Thereby, the controller 18 can accurately determine whether the semiconductor laser device 12 normally operates or not in accordance with each of current values flowing from the laser driving circuit 10 into the semiconductor laser device 12, and therefore can appropriately output the turn-off signal to the laser driving circuit 10 so as to substantially stop applying a power supply to the laser device 12. When the voltage outputted from the detecting circuit 15 is less than 2.67 volts, the controller 18 can store 0 volts as the threshold at the threshold memory 20.

Thereby, when the current flowing from the laser driving circuit 10 into the semiconductor laser device 12 is less than a predetermined value (1,200 milliamperes in a case shown in FIG. 2b) due to a decrease of the battery voltage and the like, the controller 18 cannot output the turn-off signal to the laser driving circuit 10 so as to substantially stop applying a power supply to the semiconductor laser device 12 but the controller 18 can determine that the laser device 12 normally operates regardless of the amount of the light received by the photo detector 16.

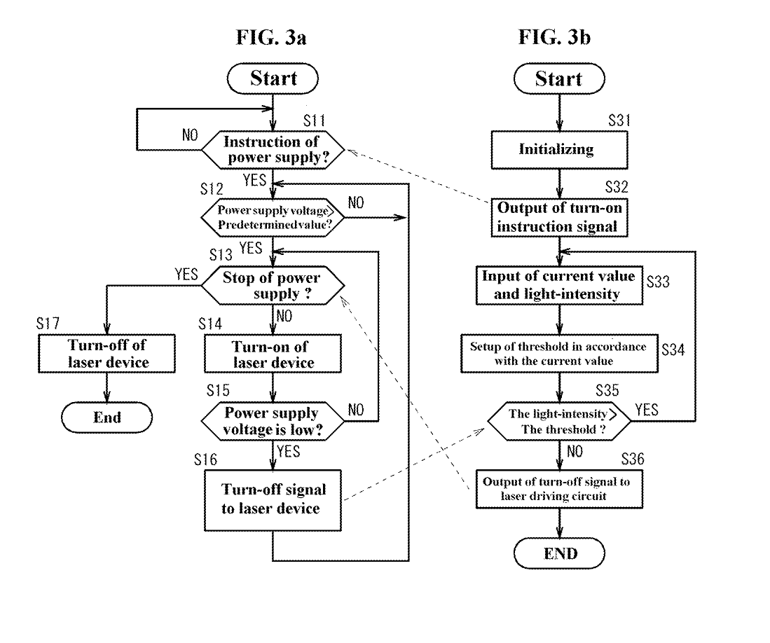

Exemplary operations of the vehicle headlight system will now be described with reference to flow charts shown by FIGS. 3a and 3b, which shows exemplary operations of the laser driving circuit 10 and the controller 18 of the vehicle headlight system, wherein relations between the laser driving circuit 10 and the controller 18 are shown by dot-lines, respectively.

The laser driving circuit 10 can wait for an instruction of power supply output from the controller 18 (NO in Step S11). When the laser driving circuit 10 inputs the instruction of power supply from the controller 12 (YES in Step S11), the laser driving circuit 10 can determine whether a power supply voltage is higher than a predetermined value or not (Step S12). When the power supply voltage is lower than the predetermined value, the laser driving circuit 10 cannot apply the power supply voltage to the semiconductor laser device 11 (NO in Step S12).

When the power supply voltage is higher than the predetermined value, the laser driving circuit 10 can apply the power supply voltage to the semiconductor laser device 11 (YES in Step S12). While the laser driving circuit 10 does not input the turn-off signal (stop instruction of the power supply) output from the controller 18 (NO in Step S13), the laser driving circuit 10 can turn on the semiconductor laser device 12 (Step S14). While the laser driving circuit 10 detects that the power supply voltage is not lower than the predetermined value, the laser driving circuit 10 can repeat processes after Step S13 (NO in Step S15).

When the laser driving circuit 10 detects that the power supply voltage is lower than the predetermined value, the laser driving circuit 10 can output the turn-off signal to the semiconductor laser device 11 (Step S16), and can return to Step S12. When the laser driving circuit 10 inputs the turn-off signal (stop instruction of the power supply) output from the controller 18 (YES in Step S13), the laser driving circuit 10 can turn off the semiconductor laser device 12 (Step S17).

As shown in FIG. 3b, the vehicle head light can initialize the controller 18 when the headlight switch 5 turns on (Step S31), and the controller 18 can output a turn-on instruction signal of the power supply to the laser driving circuit 10 to turn on the semiconductor laser device 12 (Step S32). The controller 18 can input the current value, which flows from the laser driving circuit 10 into the laser device 12, from the detecting circuit 15, and also can input the light-intensity of the slightly part of the light, which is received by the photo detector 16, from the receiver circuit 17 (Step S33).

Next, the controller 18 can store the threshold at the threshold memory 20 with respect to the light-intensity output from the receiver circuit 17 in accordance with the current value output from the detecting circuit 15 (Step S34), as described above with reference to FIG. 2a and FIG. 2b. The controller 18 can determined whether the light-intensity of the light having the substantially white color tone output from the receiver circuit 17 is higher than the threshold or not (Step S35). When the light-intensity of the light is higher than the threshold, the controller 18 can repeat the process after Step S33 by returning to Step S33 (YES in Step S35).

When the light-intensity of the light having the substantially white color tone is lower than the threshold (NO in Step S35), the controller 18 can output the turn-off signal to the laser driving circuit 10 so as to turn off the semiconductor laser device 12 (Step S36). As described above, the controller 18 can store a lower threshold with a decrease in the current value, which flows from the laser driving circuit to the semiconductor laser device, at the threshold memory 20, and therefore cannot determine that the light-intensity of the light having the substantially white color tone is lower than the threshold in Step S35, even when the light-intensity decreases due to a decrease of the current value flowing into the semiconductor laser device 12.

According to the exemplary vehicle headlight system, the exemplary vehicle headlight system can provide a favorable light distribution pattern by using the light having the substantially white color tone wavelength-converted by the wavelength converting material 13 and the laser beam having a high light-intensity emitted from the semiconductor laser device 12 via the light distribution adjustment 14 to safely drive at night, while watching the abnormal state in the optical structure such as the semiconductor laser device 12, the wavelength converting material, etc.

In addition, the controller 18 can detect the abnormal state in the optical structure by determining whether the light-intensity received from the receiver circuit 17 is lower than a threshold stored at the threshold memory 20 or not. Accordingly, the controller 18 can enable the laser driving circuit 10 not to emit the laser beam from the semiconductor laser device 12 by outputting the turn-off signal to the laser driving circuit 10, and the laser driving circuit 10 can also detect that the power supply voltage becomes higher than the predetermined value. Next, when the power supply voltage becomes higher than the predetermined value as described in Step S12, the laser driving circuit 10 can apply the power supply voltage to the semiconductor laser device 11 so as to be able to emit the laser beam form the semiconductor laser device 12.

Thus, the vehicle headlight system of the disclosed subject matter can provide a favorable light distribution pattern by using the light having the substantially white color tone wavelength-converted by the wavelength converting material 13 and the laser beam having the high light-intensity, even when the battery voltage immediately returns the normal state after the controller 18 outputs the turn-off signal to the laser driving circuit 10 so as not to emit the laser beam from the semiconductor laser device 12 by detecting the abnormal state in the optical structure such as the semiconductor laser device 12, the wavelength converting material 13 and the like because the battery voltage largely decreases due to a large load such as a starter, etc.

Various modifications of the above disclosed embodiments can be made without departing from the spirit and scope of the presently disclosed subject matter. For example, cases where the above-described thresholds are stored at the threshold memory 20 in accordance with the tables such as shown in FIG. 2a and FIG. 2b. However, the thresholds are not limited to this method and can be stored at the threshold memory 20 by using a relational expression between the current value flowing from the laser driving circuit 10 into the semiconductor laser device 12 and the voltage outputted from the receiver circuit 17 corresponding to the amount of the light the light-intensity of the light having the substantially white color tone or the amount of the light. In addition, cases where the thresholds are stored at the threshold memory 20 in accordance with the current value flowing from the laser driving circuit 10 into the semiconductor laser device 12. However, the thresholds can also be stored at the threshold memory 20 by detecting whether the current value flowing from the laser driving circuit 10 into the semiconductor laser device 12 is zero or not.

While there has been described what are at present considered to be exemplary embodiments of the invention, it will be understood that various modifications may be made thereto, and it is intended that the appended claims cover such modifications as fall within the true spirit and scope of the invention. All conventional art references described above are herein incorporated in their entirety by reference.

What is claimed is:

1. A vehicle headlight system, comprising:
a laser driving circuit configured to receive a power supply from a battery incorporated into a subject vehicle, which incorporates the vehicle headlight system, via a headlight switch;
a semiconductor laser device configured to emit a laser beam by the laser driving circuit;
a current detector configured to detect a current flowing from the laser driving circuit into the semiconductor laser device;
a wavelength converting material configured to emit light having a substantially white color tone using the laser beam emitted from the semiconductor laser device;
a light distribution adjustment configured to receive the light having the substantially white color tone from the wavelength converting material, and configured to provide light distribution patterns in a forward direction of the subject vehicle by using the light emitted from the wavelength converting material;
a detecting circuit configured to input current data output from the current detector, and configured to detect the current value, which flows from the laser driving circuit into the semiconductor laser device, from the current detector;
a photo detector configured to receive a part of the light, which is emitted from the wavelength converting material;
a receiver circuit configured to detect a light-intensity of the part of the light, which is received by the photo detector;
a controller including a threshold memory, configured to output a turn-on signal to the laser driving circuit after the controller is initialized when the headlight switch turns on, and configured to output a turn-off signal to the laser driving circuit when the light-intensity received from the receiver circuit is lower than a threshold stored at the threshold memory;
a constant voltage circuit configured to apply a substantially constant voltage to the controller; and wherein the laser driving circuit is configured to emit the laser beam from the semiconductor laser device when a power supply voltage received from the battery is higher than a predetermined voltage after the laser driving circuit inputs the turn-on signal output from the controller.

2. The vehicle headlight system according to claim 1, wherein a resistance connects between the laser driving circuit and the semiconductor laser device as the current detector.

3. The vehicle headlight system according to claim 1, wherein a blue laser chip is employed as a laser chip for the semiconductor laser device.

4. The vehicle headlight system according to claim 1, wherein the wavelength converting material includes at least one of a red phosphor, a green phosphor, a blue phosphor and an yellow phosphor.

5. The vehicle headlight system according to claim 1, wherein the light distribution adjustment includes at least one of at least one reflector and a projector lens.

6. The vehicle headlight system according to claim 1, wherein the photo detector includes at least one of a photo diode and a photo transistor.

7. The vehicle headlight system according to claim 1, wherein the controller includes a computer system including a central processing unit (CPU), a read-only memory (ROM), a random access memory (RAM).

8. The vehicle headlight system according to claim 1, wherein at least one of the receiver circuit and the detecting circuit is integrated into the controller.

9. The vehicle headlight system according to claim 1, wherein the predetermined voltage in order for the laser driving circuit to emit the laser beam from the semiconductor laser device is setup between 9 volts and 18 volts.

10. The vehicle headlight system according to claim 1, wherein the constant voltage circuit applies either substantially 3.3 volts or 5 volts to the controller.

11. The vehicle headlight system according to claim 1, wherein the controller stores a plurality of thresholds at the threshold memory.

12. The vehicle headlight system according to claim 1, wherein the controller stores a lower threshold with a decrease in the current value, which flows from the laser driving circuit to the semiconductor laser device, at the threshold memory.

13. The vehicle headlight system to claim 1, wherein a blue laser chip emitting a blue laser beam is employed as a laser chip for the semiconductor laser device, and an yttrium aluminum garnet (YAG) phosphor ceramic is employed as the wavelength converting material.

14. The vehicle headlight system according to claim 2, wherein the predetermined voltage in order for the laser driving circuit to emit the laser beam from the semiconductor laser device is setup between 9 volts and 18 volts.

15. The vehicle headlight system according to claim 3, wherein the predetermined voltage in order for the laser driving circuit to emit the laser beam from the semiconductor laser device is setup between 9 volts and 18 volts.

16. The vehicle headlight system according to claim 4, wherein the predetermined voltage in order for the laser driving circuit to emit the laser beam from the semiconductor laser device is setup between 9 volts and 18 volts.

17. The vehicle headlight system according to claim 5, wherein the predetermined voltage in order for the laser driving circuit to emit the laser beam from the semiconductor laser device is setup between 9 volts and 18 volts.

18. The vehicle headlight system according to claim 6, wherein the predetermined voltage in order for the laser driving circuit to emit the laser beam from the semiconductor laser device is setup between 9 volts and 18 volts.

19. The vehicle headlight system according to 7, wherein the predetermined voltage in order for the laser driving circuit to emit the laser beam from the semiconductor laser device is setup between 9 volts and 18 volts.

20. The vehicle headlight system according to claim 8, wherein the predetermined voltage in order for the laser driving circuit to emit the laser beam from the semiconductor laser device is setup between 9 volts and 18 volts.
